(19) United States
(12) Patent Application Publication
(10) Pub. No.: US 2022/0084286 A1
(43) Pub. Date: Mar. 17, 2022

(54) OPTIMIZED MESH REPRESENTATIONS

(71) Applicant: Hewlett-Packard Development Company, L.P., Spring, TX (US)

(72) Inventor: Prakash Reddy, Palo Alto, CA (US)

(73) Assignee: Hewlett-Packard Development Company, L.P., Spring, TX (US)

(21) Appl. No.: 17/420,069

(22) PCT Filed: Jan. 11, 2019
(86) PCT No.: PCT/US2019/013148

§ 371 Date: Jun. 30, 2021

(51) Int. Cl. G06T 17/20; G06T 17/10; G06T 17/05; G06F 30/10

(52) U.S. Cl. CPC G06T 17/20; G06F 30/10; G06T 17/05; G06T 17/10

(57) ABSTRACT

In example implementations, an apparatus is provided. The apparatus includes a validator, a decimator, and a processor. The processor is communicatively coupled to the validator and the decimator to control operation of the validator and the decimator. The validator is to detect errors in a computer generated three-dimensional (3D) object model and mark locations that have errors. The decimator is to reduce a resolution of the computer generated 3D object model excluding the locations that are marked with the errors to generate an optimized mesh representation of the computer generated 3D object model.

### BACKGROUND

Three-dimensional (3D) printers can be used to print 3D objects. The 3D printers can perform an additive printing process. A variety of different 3D printers are available and can use a variety of different 3D printing processes.

A 3D printer may print a 3D object based on a computer generated 3D model. The 3D model may be generated on a computer aided drawing (CAD) program. The 3D model may then be provided to the 3D printer and the 3D printer may print the object based on the 3D model.

### BRIEF DESCRIPTION OF THE DRAWINGS

FIG. 1 is a block diagram of an example 3D printing system of the present disclosure;

FIG. 2 is a block diagram of the apparatus to optimize mesh representations of a three-dimensional model of the present disclosure;

FIG. 3 illustrates an example of a three-dimensional model that has been optimized of the present disclosure;

FIG. 4 is a flow chart of an example method for optimizing mesh representations of a three-dimensional model of the present disclosure; and

FIG. 5 is a block diagram of an example non-transitory computer readable storage medium storing instructions executed by a processor to optimize mesh representations.

### DETAILED DESCRIPTION

Examples described herein provide a method and apparatus to optimize mesh representations of 3D models used for 3D printing. As discussed above, 3D object models may be generated for 3D printers. The 3D printers may print objects based on the 3D object models.

The 3D object models may be rendered as tessellations of triangles. The larger the number of triangles, the higher the resolution and the smoother the surface in the final 3D printed object. Processing the 3D object models with a high resolution (e.g., a large number of triangles) can consume large amounts of processing resources and memory and increases the time to render for viewing. As a result, the 3D object can undergo a decimation process that reduces the number of triangles.

However, the 3D object model may also undergo a validation process that may detect errors. The errors may include a side shared by more than two triangles, manifold errors, incorrect thickness of walls, and the like. When the 3D object undergoes the decimation process and the resolution is reduced, the detail of the detected errors may be lost.

Examples herein provide a method and apparatus that may mark the triangles that have errors in a 3D object model. The marked 3D object model may then undergo the decimation process. However, the marked triangles may not be reduced, such that the original resolution of the marked errors is preserved. The modified decimation process may generate an optimized mesh representation that includes detected errors at an original resolution. As a result, the optimized mesh representation may reduce the processing and memory that is consumed to process the optimized mesh representation. However, the original resolution of triangles with errors may be kept so that the errors can be fixed when working with the optimized mesh representation.

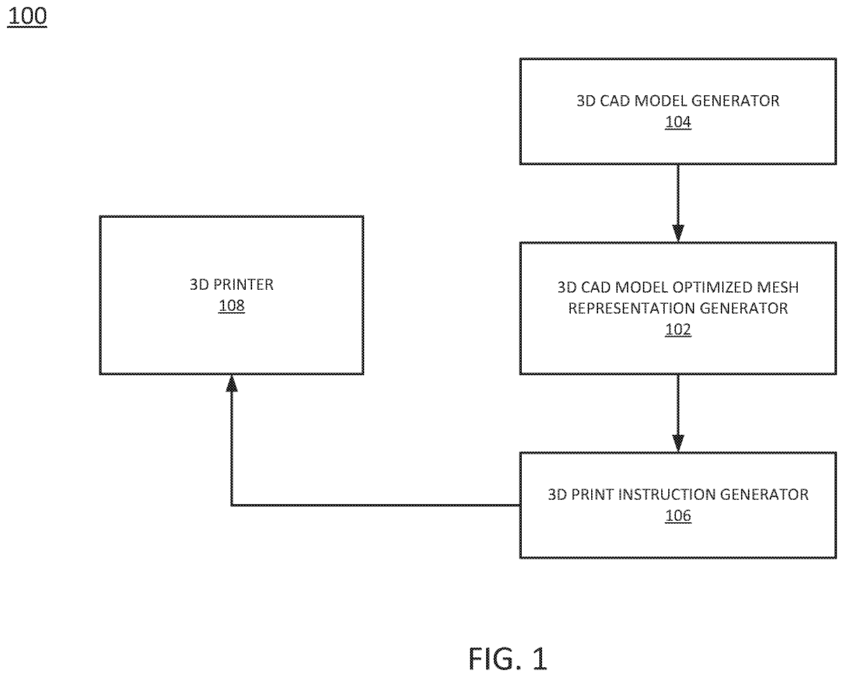

FIG. 1 illustrates an example 3D printing system 100 of the present disclosure. In one example, the 3D printing system 100 may include an optimized mesh representation generator 102. The optimized mesh representation generator 102 may be a computing device that includes a processor and a memory that stores instructions executed by the processor to perform the functions described herein.

In one example, the optimized mesh representation generator 102 may generate an optimized mesh representation of a 3D object model. In one example, the 3D object model may be received from a 3D computer aided drawing (CAD) model generator 104. The 3D object model may be a computer generated representation of an object that may be printed by a 3D printer 108.

In one example, the optimized mesh representation may be a computer rendered version of the 3D object model that includes tessellations in a reduced resolution and an original resolution. Tessellations may comprise a mesh of triangles that are used to represent the 3D object model. For example, the 3D printer 108 may print in straight lines. Thus, the tessellations may break up 3D objects with curved surfaces into many small triangles. The larger the number of triangles, the higher the resolution and the smoother the surface of the final printed object may be.

The tessellations in a reduced resolution may be locations or triangles that were detected to be error free after being examined as part of a validation process and then reduced as part of a decimation process. The decimation process may be a process that is applied to the rendered 3D object model to reduce the resolution of the 3D object model. For example, a number of triangles can be reduced by merging into larger triangles.

In one example, the level of decimation may be user defined. For example, the user may set the decimation level to 50%, 30%, 25%, and the like, of the original resolution. In one example, the level of decimation may be set on the fly. For example, for one 3D object model, the decimation may be set to 50% and then changed to 30% for different portions of the 3D object model or for a subsequent 3D object model.

The tessellations in an original resolution may be locations or triangles that were marked for exclusion from a decimation process. In one example, the optimized mesh representation generator 102 may include a user interface that allows a user to select certain locations or regions of the 3D object model. The user may want to view certain locations in detail after the decimation process. The locations may be marked such that the original resolution of the marked locations is maintained after the decimation process.

In one example, the tessellations in an original resolution may be locations or triangles that were detected to contain errors as part of the validation process. The locations with errors can be marked as part of the validation process. The marked locations can be excluded from the decimation process and kept in the original resolution.

As a result, the optimized mesh representation may provide a rendered 3D object model that consumes less memory and less processing power to view and correct errors. However, the marked locations in the optimized mesh representation may be kept at an original higher resolution to provide a detailed view or allow the errors to be accurately seen and corrected.

After the optimized mesh representation is viewed and/or the errors are corrected, the rendered 3D object model may be provided to a 3D print instruction generator 106. In one example, if the 3D object model contains no marked locations, the 3D object model may undergo the decimation process and be provided to the 3D print instruction generator 106.

In one example, the 3D print instruction generator 106 may provide instructions that are executable by the 3D printer 108. For example, the instructions may be in a G-code format. The 3D printer 108 may then print the desired object in accordance with the 3D print instructions provided by the 3D print instruction generator 106.

It should be noted that although the 3D CAD model generator 104, the optimized mesh representation generator 102, and the 3D print instruction generator 106 are illustrated as different components in FIG. 1, that the 3D CAD model generator 104, the optimized mesh representation generator 102, and the 3D print instruction generator 106 may be combined as part of a single computing device. For example, the 3D CAD model generator 104, the optimized mesh representation generator 102, and the 3D print instruction generator 106 may be stored as instructions in memory that are executed by a processor of a single computing device.

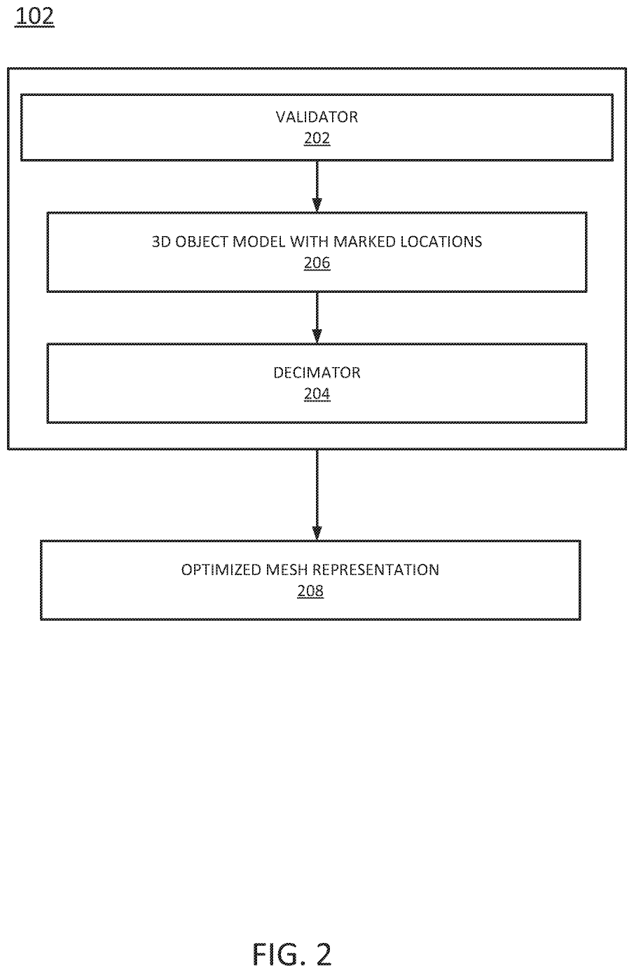

FIG. 2 illustrates a block diagram of the optimized mesh representation generator 102 that is used to detect errors and mark locations with errors in a 3D object model. In one example, the optimized mesh representation generator 102 may include a validator 202 and a decimator 204. The validator 202 and the decimator 204 may be implemented in hardware (e.g., specially programmed application specific integrated circuit (ASIC) chips) or may be deployed as instructions stored in memory that are executed by a processor.

In one example, the validator 202 may perform the validation process described above. For example, the validator 202 may detect errors in a computer generated 3D object model from the 3D CAD model generator 104. In one example, the validator 202 may process the 3D object model and detect errors in the 3D object model and mark the locations with the errors to generate a 3D object model with marked locations 206.

In one example, the validator 202 may generate a list of errors that are detected in the 3D object model and the locations may be marked based on the list of errors that are detected. In one example, the validator 202 may mark the locations as the errors are detected in the 3D object model. In other words, the locations may be marked on-the-fly as the validator 202 is processing the 3D object model. The locations may be shown on a display as they are being marked by the validator 202.

In one example, the errors may be any errors that are generated when the 3D object model is rendered into a mesh of triangles or tessellations. The errors may include manifold errors, errors associated with a side that is shared by more than two triangles, an incorrect thickness of a wall of a triangle, and the like. The above are some examples of errors, but any type of error that can be generated in a rendered 3D object model may be marked by the validator 202.

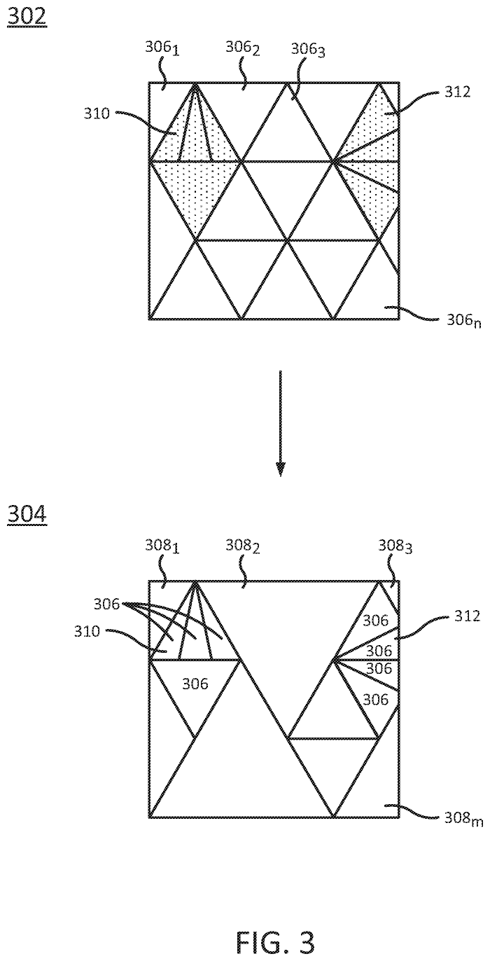

FIG. 3 illustrates an example of a portion 302 of a 3D object model with marked locations 206 that is output by the validator 202. It should be noted that the portion 302 of the 3D object model is shown as a two-dimensional portion of the overall 3D object model with tessellations for ease of explanation. The actual 3D object model that is rendered with a mesh of triangles that form a three dimensional object may include thousands of triangles depending on a resolution of the rendering. The 3D object model can be rotated, rolled, flipped, or manipulated into any desired view on a display of a computing device.

In one example, the 3D object model may be rendered with a mesh of triangles 306₁ to 306ₙ (hereinafter also referred to individually as a triangle 306 or collectively as triangles 306). The validator 202 may examiner each triangle 306 in the 3D object model to detect errors, as shown in the portion 302. As discussed above, a variety of different errors can be detected in the 3D object model.

When the validator 202 detects a location of the 3D object model with an error, the validator 202 may mark the location, as shown in the portion 302. For example, locations 310 and 312 of the 3D object model may include errors. For example, a side may be shared by more than two triangles in the location 310 or a thickness of the walls may be incorrect in the location 312. Although two locations 310 and 312 are illustrated in FIG. 3, it should be noted that any number of locations may be detected with errors in the 3D object model by the validator 202. Although the locations 310 and 312 include a group of triangles 306, it should be noted that the locations 310 and 312 may include an edge of a triangle, a face of a single triangle, a vertex of a triangle, and the like.

In one example, the validator 202 may provide a visual marking to be shown to a user on a display. For example, the validator 202 may shade the locations 310 and 312. In one example, the validator 202 may use thicker lines around the triangles in the locations 310 and 312. In one example, the validator 202 may draw the triangles in the locations 310 and 312 with a different color (e.g., red to indicate an error). Any type of visual marking may be used to mark the locations 310 and 312 in the 3D object model that include errors.

In one example, the validator 202 may also mark the machine readable code that is associated with the 3D object model. For example, the 3D object model with marked locations 206 discussed in FIG. 2 may include a visual representation as shown by the 3D object model 302 in FIG. 3 and a machine readable code. In one example, the portions of the code that correspond with the triangles 306 in the locations 310 and 312 may also be marked with annotations or text in the code. The machine readable code may be used by the decimator 204 to perform the decimation.

As noted above, in some examples the marked locations may be selected by a user. For example, the optimized mesh representation generator 102 may include a user interface to allow a user to select, draw around, highlight, and the like, certain locations to be excluded from the decimation process. The selected locations may also be marked with visual markings, as described above. It should be noted that the marked locations may include a combination of both user selected locations and/or locations that are detected to have an error by the validator 202.

Referring, back to FIG. 2, the decimator 204 may receive the 3D object model with the marked locations 206 from the validator 202. The decimator may then perform a decimation process on the 3D object model with the marked locations 206 on all triangles 306 except the triangles 306 in the marked locations 310 and 312.

As discussed above, the decimator 204 may perform a decimation process that reduces the resolution of the 3D object model 302. The level of decimation may be user defined and can be changed on the fly. For example, a resolution of a first 3D object model may be reduced by 50% and a resolution of another 3D object model may be reduced by 30%, and so forth. In one example, the resolution of a first portion of a 3D object model may be set to 70% and the resolution of another portion of the 3D object model may be set to 60%, and so forth. The decimation process may reduce the resolution of the 3D object model 302 to reduce the amount of memory and processing resources that are used to view and edit the 3D object model.

The decimator 204 may generate an optimized mesh representation 208 after applying the decimation process to the 3D object model with marked locations 206. FIG. 3 illustrates a portion 304 of the optimized mesh representation 208 that is generated by the decimator 204. It should be noted that the portion 304 illustrates a two-dimensional view of a portion of the optimized mesh representation 208 for ease of explanation. However, the optimized mesh representation 208 may include hundreds to thousands of tessellated triangles to form a three-dimensional object that is similar in size and shape to the 3D object model.

FIG. 3 illustrates how the locations 310 and 312 were not processed by the decimator 204. For example, the triangles 306 in locations that are not marked may be combined to form larger triangles 308₁-308ₘ (hereinafter also referred to individually as a triangle 308 or collectively as triangles 308), as shown in the portion 304. Combining the smaller triangles 306 into larger triangles 308 may reduce the resolution of the 3D object model, thereby consuming less memory and processing resources to view and edit.

In some instances, some triangles 306 that are near marked locations 310 and 312 may not have other triangles 306 that can be combined. As a result, the resolution of some triangles 306 that have no errors may not be reduced.

However, as noted above, the locations 310 and 312 that are marked in the 3D object model with marked locations 206 (as shown by the portion of the 3D object model 302) may not be processed by the decimator 204. Said another way, the triangles 306 in the locations 310 and 312 are excluded from the decimation process.

As can be seen in the portion 304 of the optimized mesh representation 208 of the 3D object model, the triangles 306 in the marked locations 310 and 312 are kept at an original resolution. Meanwhile, the remaining triangles 308 are processed to a reduced resolution.

Thus, the optimized mesh representation 208 provides a model that has a reduced resolution, while maintaining the original resolution of those locations that were marked with errors by the validator 202. In other words, the locations that are marked with errors may be identified and the resolution of those locations may be unchanged in the optimized mesh representation 208. As a result, the optimized mesh representation 208 may be used to view the locations 310 and 312 in detail in the original resolution. The errors in the locations 310 and 312 can be accurately fixed using the optimized mesh representation 208. At the same time, the optimized mesh representation 208 reduces the memory and processing used to view the object.

In other words, the optimized mesh representation 208 is “optimized” in that the optimized mesh representation 208 strikes a balance between reducing the resolution of a majority of the 3D object model to reduce memory and processor consumption, while maintaining the higher resolution of the locations marked with errors to allow for accurate error correction in the 3D object model. With the optimized mesh representation 208, a user may use a single model rather than going back and forth between two different models when trying to correct errors detected by the validator 202.

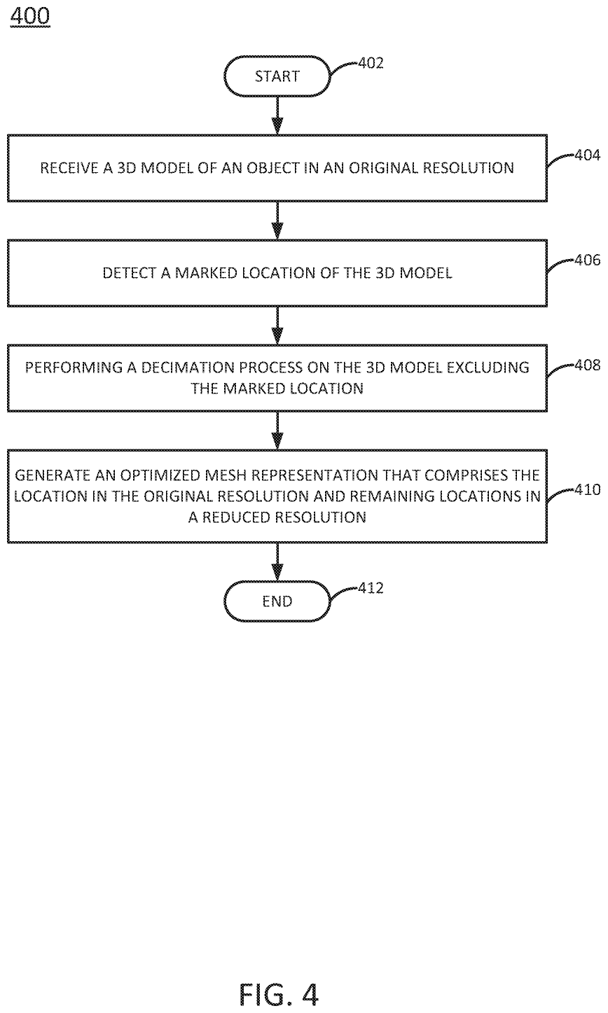

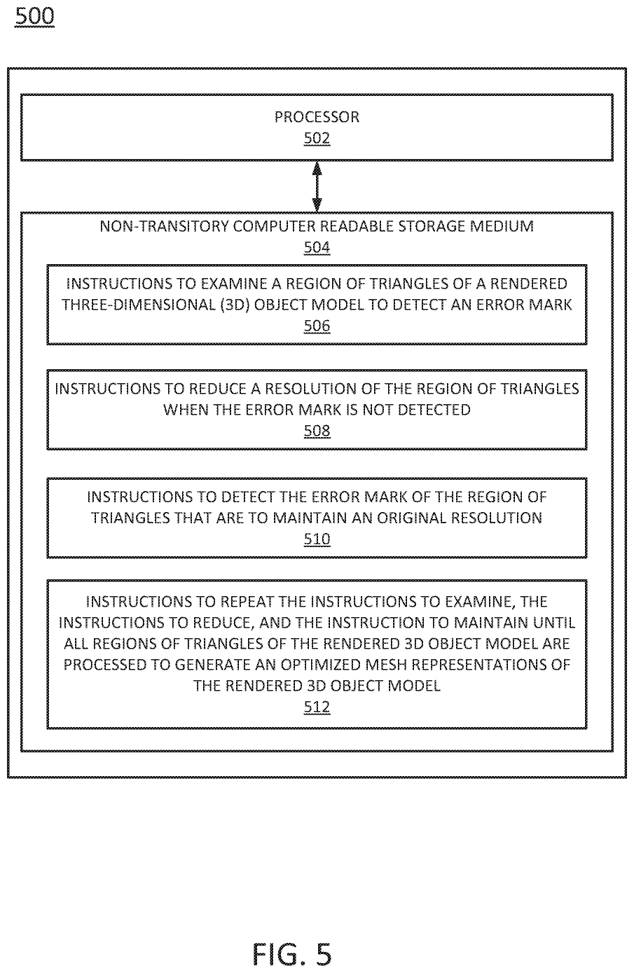

FIG. 4 illustrates a detailed flow chart of a method for optimizing mesh representations of a three-dimensional model of the present disclosure. In an example, the method 400 may be performed by the optimized mesh representation generator 102 illustrated in FIGS. 1 and 2, or the apparatus 500 illustrated in FIG. 5, and described below.

At block 402, the method 400 begins. At block 404, the method 400 receives a 3D model of an object in an original resolution. In one example, the 3D model may be a computer generated model of an object that is to be printed by a 3D printer. The 3D model may be rendered to include a tessellation of triangles. As noted above, the 3D printer may print in straight lines. Thus, to allow the 3D printer to print curved surfaces, the object may be processed as a tessellation of small triangles. The larger the number of triangles, the greater the resolution and the smoother the surface of the printed object. The smaller the number of triangles, the lower the resolution, and the curved surfaces may be printed with rougher surfaces.

At block 406, the method 400 detects a marked location of the 3D model. In one example, the marked location may be selected by a user. For example, the user may want to view certain regions in detail in the original resolution. Thus, certain locations in the 3D model may be marked for exclusion from the decimation process.

In one example, the marked location may be a location that contains an error. For example, a validator may perform a validation process on the 3D model to detect errors. The errors may include manifold errors, errors related to an incorrect thickness of a wall, errors due to a side being shared by more than two triangles, and the like.

The locations with errors may be marked. In one example, the errors may be marked visually for display and may also be marked in machine readable code that is processed and executed by a decimator. The marks in the locations for visual display may include shading, coloring, changing a thickness of lines that form the triangles in the marked locations, and the like. In one example, the locations may be marked on-the-fly as the validator 202 is processing the 3D model for errors.

In one example, the errors may also be marked with annotations, comments, or text in the machine readable code. For example, the tessellation of triangles of the 3D object may also be represented as machine readable code that is processed by a decimator. The portions of the code that represent the locations that are detected with errors can be marked. For example, a symbol (e.g., an asterisk, brackets, and the like) may be used to annotate the portions of code. In another example, comments may be added to the portions of the code that represent the locations that are detected with errors (e.g., comments or text such as [error location do not decimate] may be added).

At block 408, the method 400 performs a decimation process on the 3D model excluding the marked location. In one example, a decimator may perform a decimation process to reduce the resolution of the 3D model. Reducing the resolution may cause a number of triangles used in the tessellation to be reduced. An amount of decimation may be defined by a user. For example, the amount of decimation may be set to a percentage of reduction of the resolution (e.g., 30%, 50%, 75%, and the like).

However, the locations that are marked may be excluded from the decimation process. For example, as the decimator is processing the machine readable code with marked locations, the decimator may read the annotations or markings of the marked locations. The decimator may skip over the marked locations and maintain the marked locations at an original resolution.

At block 410, the method 400 generates an optimized mesh representation that comprises the location in the original resolution and remaining locations in a reduced resolution. In other words, the optimized mesh representation may include locations that have an original resolution and locations that have a reduced resolution. The locations that have an original resolution may be locations where errors were detected.

In one example, the optimized mesh representation may allow a user to view the marked locations in the original resolution. The original resolution may allow certain portions of the 3D model to be viewed in detail or the errors to be accurately fixed in the optimized mesh representation. The reduction of the resolution of the remaining portions of the 3D model may allow the optimized mesh representation to be easily rotated, rolled, manipulated, and the like, to be efficiently to viewed. In contrast, using the 3D model in the original resolution may be inefficient as processing of the 3D model may take several minutes each time the 3D model is moved to change a view due to the large consumption of memory and processing resources. Using a completely decimated 3D model may also lead to inaccurate error corrections as a user may not be able to view the errors correctly in a reduced resolution.

In one example, the optimized mesh representation may be converted into 3D print instructions for a 3D printer. The instructions may be sent to the 3D printer to print the object. At block 412, the method 400 ends.

FIG. 5 illustrates an example of an apparatus 500. In an example, the apparatus 500 may be the optimized mesh representation generator 102. In an example, the apparatus 500 may include a processor 502 and a non-transitory computer readable storage medium 504. The non-transitory computer readable storage medium 504 may include instructions 506, 508, 510, and 512 that, when executed by the processor 502, cause the processor 502 to perform various functions.

In an example, the instructions 506 may include instructions to examine a region of triangles of a rendered three-dimensional (3D) object model to detect an error mark. The instructions 508 may include instructions to reduce a resolution of the region of triangles when the error mark is not detected. The instructions 510 may include instructions to detect the error mark of the region of triangles that are to maintain an original resolution. The instructions 512 may include instructions to repeat the instructions to examine, the instructions to reduce, and the instructions to maintain until all regions of triangles of the rendered 3D object model are processed to generate an optimized mesh representation of the rendered 3D object model.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. An apparatus, comprising:
a validator to detect errors in a computer generated three-dimensional (3D) object model and mark locations that have errors; and
a decimator to reduce a resolution of the computer generated 3D object model excluding the locations that are marked with the errors to generate an optimized mesh representation of the computer generated 3D object mode.

2. The apparatus of claim 1, further comprising:
a memory to store the computer generated 3D object model and the optimized mesh representation.

3. The apparatus of claim 1, wherein the computer generated 3D object model comprises a tessellation of triangles.

4. The apparatus of claim 3, wherein the resolution of the computer generated 3D object model is reduced by the decimator by reducing a number of the triangles.

5. The apparatus of claim 4, wherein the locations comprises a subset of triangles.

6. The apparatus of claim 5, wherein an original size of the subset of triangles is maintained in the optimized mesh representation while a size of remaining triangles is increased to reduce the resolution to generate the optimized mesh representation.

7. A method, comprising:
receiving, by a processor, a 3D model of an object in an original resolution;
detecting, by the processor, a marked location of the 3D model;
performing, by the processor, a decimation process on the 3D model excluding the marked location; and
generating, by the processor, an optimized mesh representation that comprises the marked location in the original resolution and remaining locations in a reduced resolution.

8. The method of claim 7, wherein the marked location is user selected.

9. The method of claim 7, wherein the marked location comprises a location with an error in the 3D model.

10. The method of claim 9, further comprising:
fixing, by the processor, the error in the optimized mesh representation.

11. The method of claim 7, wherein the marked location comprises a triangle of a plurality of tessellated triangles in the 3D model.

12. The method of claim 11, wherein the marked location comprises an edge, a face, or a vertex of the triangle.

13. A non-transitory computer readable storage medium encoded with instructions executable by a processor, the non-transitory computer-readable storage medium comprising:
instructions to examine a region of triangles of a rendered three-dimensional (3D) object model to detect an error mark;
instructions to reduce a resolution of the region of triangles when the error mark is not detected;
instructions to detect the error mark of the region of triangles that are to maintain an original resolution; and
instructions to repeat the instructions to examine, the instructions to reduce, and the instruction to maintain until all regions of triangles of the rendered 3D object model are processed to generate an optimized mesh representation of the rendered 3D object model.

14. The non-transitory computer readable storage medium of claim 13, wherein the error mark is generated based on a list of errors detected by a validator.

15. The non-transitory computer readable storage medium of claim 13, wherein an amount that the resolution is reduced is user-defined.
